(19) United States
(12) Patent Application Publication
(10) Pub. No.: US 2003/0052711 A1
(43) Pub. Date: Mar. 20, 2003

(54) Despreader/correlator unit for use in reconfigurable chip

(76) Inventors: Bradley L. Taylor, Oakland, CA (US); Gary N. Lai, Sunnyvale, CA (US)

Correspondence Address: ROBERT E. KREBS, THELEN REID & PRIEST LLP, P.O. BOX 640640, SAN JOSE, CA, 95164-0640, US

(21) Appl. No.: 09/960,710

(22) Filed: Sep. 19, 2001

(51) Int. Cl. H03K 19/173

(52) U.S. Cl. 326/38

(57) ABSTRACT

A reconfigurable chip includes a despreader/correlator function back in order to better implement communication protocols which require despreading and/or correlation. These despreader/correlation functional blocks are used in addition to reconfigurable functional blocks having arithmetic logic units. The functions of the despreader/correlator functional blocks are preferably controlled by instructions from a local instruction memory.

### BACKGROUND OF THE INVENTION

The present invention relates to reconfigurable chips for use in implementing communication algorithms.

### STATE OF THE ART

Reconfigurable logic is becoming more and more important, especially as reconfigurable logic systems are used to implement algorithms. These systems are often called reconfigurable computing systems. Reconfigurable computing systems are useful in many fields, especially for communications systems, in which a large amount of processing needs to be done. Reconfigurable computing systems can distribute the processing over the chip rather than focus the processing at a single central processing unit. Typically, the reconfigurable functional units or data path units are used throughout the chip to implement different functions. Although this allows a greater level of functionality for use with different algorithms, in some cases it is desirable to have a reconfigurable chip with units designed to implement certain functions commonly used in communication algorithms. For this reason, it is desired to have an improved reconfigurable chip for use with communication algorithms.

### SUMMARY OF THE INVENTION

The present invention is a reconfigurable chip which adds a despreader/correlator unit in a reconfigurable fabric for the unit. In a preferred embodiment, the despreader/correlator units are placed in multiplier blocks distributed throughout the reconfigurable fabric.

A popular communication algorithm is the code division multiple access (CDMA) algorithms. These systems often use a pseudo noise code to distribute the power of the signal over a bandwidth greater than the bandwidth of the signal itself. Depreading is the process of taking a signal with a wide pseudo-noise (PN) spread bandwidth and using the pseudo-noise code to reconstitute it in a much narrower bandwidth. Correlators are signal processors and communication receivers that calculate the correlation function between a transmitted signal and the received signal.

One unit preferably used in the correlator/despreader is a complex multiplier. In one embodiment of the present invention, the despreader/correlator unit used in the reconfigurable chip uses a number of single-bit complex multiplier units. The complex multiplier units can be implemented using multiplexers and invertors to effectively multiply an input signal by a restricted set of values. This reduced functionality complex multiplier can be produced in a relatively small area.

By placing the despreader/correlator blocks within the multiplier blocks, the despreader/correlators can be used whenever a multiplier is not required. The despreader/correlator thus can use adder units, input muxes, and other elements of the multiplier block.

One embodiment of the present invention comprises a reconfigurable chip, including a despreader function block, including complex multiplier units. The despreader function block, including multiplexers, allows the selection of different operation configurations for the despreader function block. The despreader function block preferably acts as a correlator function block as well. In one embodiment the despreader/correlator function block shares elements with a multiplier unit.

In one preferred embodiment, the despreader function block can be interconnected to other elements in the reconfigurable chip by using interconnect elements operably connected to the despreader function block.

In another embodiment, an instruction memory is associated with the despreader function block to provide an instruction to configure the despreader function block. In another embodiment, the despreader function block includes a number of block input multiplexers. The selectable despreader tree units, including complex multiplier units, and at least one output multiplexer, are operably connected to the selectable despreader tree unit.

Another embodiment of the present invention comprises a reconfigurable chip including multiple, selectable despreader blocks; the despreader blocks adapted to despread input signals.

Another embodiment of the present invention comprises a reconfigurable chip comprising multiple despreader blocks. The despreader blocks are adapted to despread input signals using a pseudo noise sequence. The selectable blocks are also selectable to a non-despreader function and reconfigurable functional units operably connectable to the despreader blocks, reconfigurable functional units, including an arithmetic logic unit.

### BRIEF DESCRIPTION OF THE DRAWING FIGURES

FIG. 1 is a diagram of a reconfigurable chip of one embodiment of the present invention.

FIG. 2 is a diagram despreader/correlator unit of one embodiment of the present invention.

FIG. 3 is a diagram illustrating despreader/correlator units for use in the despreader/correlator block of FIG. 5.

FIG. 4 is a diagram illustrating the controls for the complex multiplier units of the despreader/correlator unit of FIG. 3.

FIG. 5 is a diagram illustrating one embodiment of a despreader/correlator tree for use in the present invention.

FIGS. 6A and 6B illustrate the operation of a complex multiplier.

FIG. 7 is a diagram of one embodiment of an implementation of a complex multiplier for use with the system of the present invention.

FIG. 8 is a diagram of an implementation of a despreader in one embodiment of present invention.

FIG. 9 is an implementation of a despreader for use in the system of the present invention.

FIG. 10 is a diagram of an implementation of a despreader integration with input and output muxes.

FIG. 11 is a diagram of correlator integration with input and output muxes.

FIG. 12 is a diagram of a correlator circuit, using delay registers to implement a correlator function.

FIG. 13 is a diagram of one despreader unit of one embodiment of the present invention.

FIG. 14 is a diagram of muxing mode options for a complex multiplier unit of one embodiment of the present invention.

FIG. 15 is a diagram of an implementation of one embodiment of the present invention.

FIG. 16 is a diagram of an implementation of the instruction provided to a despreader/correlator unit.

FIG. 17 is another diagram of the instruction provided to a despreader/correlator unit.

FIG. 18 is an implementation of the local interconnects to a despreader/correlator unit.

FIG. 19 illustrates the global connections to the elements in a tile of the reconfigurable chip.

FIG. 20 is a diagram that illustrates the interconnections of the system of FIG. 19.

FIG. 21 illustrates a layout of a despreader/correlator unit of one embodiment of the present invention.

FIG. 22A illustrates a multiplier unit for use along with the despreader/correlator unit of the present invention.

FIG. 22B illustrates an adder unit for use along with the unit of the present invention.

FIG. 23 illustrates a reconfigurable functional unit which can be used with the system of the present invention.

### DETAILED DESCRIPTION OF THE INVENTION

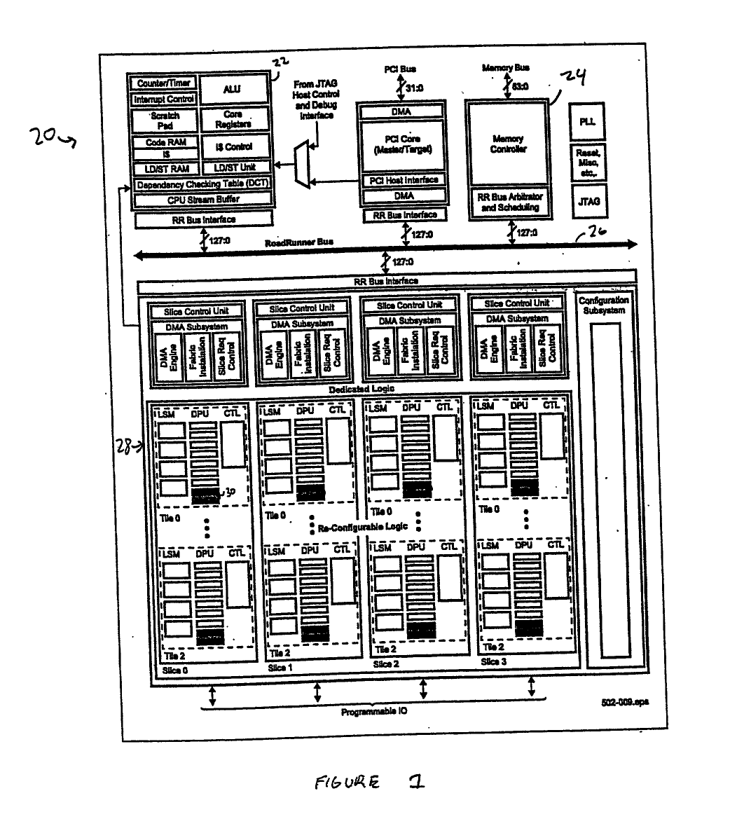

FIG. 1 illustrates a reconfigurable chip 20 for use with the system of the present invention. The reconfigurable chip 20 includes a central processing unit 22, a memory controller 24, an interface bus 26 used to obtain data from the external memory, and a reconfigurable fabric 28. The reconfigurable fabric 28 is preferably constructed of a number of slices, each comprised of a number of different tiles. As will be described below, within each tile, preferably is located a despreader/correlator block unit 30. The despreader/correlator block unit 30 preferably, also, does a multiplier function. Also shown in each tile are a number of reconfigurable functional units or data path units, which can be used to implement different functions. The despreader/correlator functions can be more effectively done by using a dedicated despreader/correlator unit, rather than being placed into generic reconfigurable functional units.

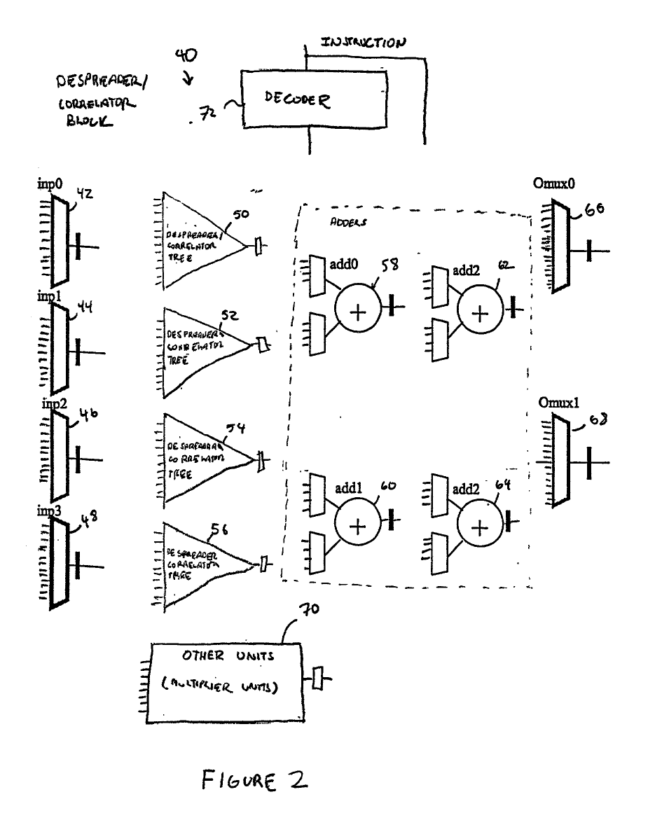

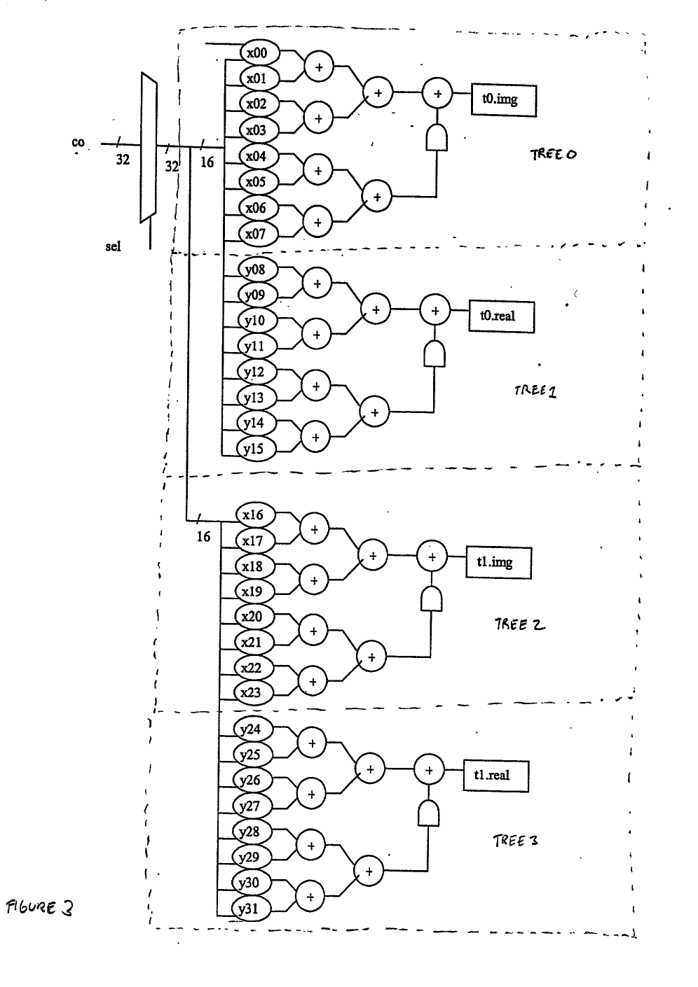

FIG. 2 is a diagram of a despreader/correlator block. The despreader/correlator block 40 includes a number of block input multiplexers 42, 44, 46, and 48. These input muliplexers preferably use a large number of inputs to produce a single output. In one embodiment, these input block multiplexers are 40 to 1 multiplexers. The signals going to the input multiplexers include local connections and global connections as described below. The despreader/correlator block also includes a number of despreader/correlator tree units 50, 52, 54 and 56. These units are preferably connectable to adder units, such as adder units 58, 62, 60 and 64. The despreader/correlator units preferably include a number of input muxes, allowing them to connect to different outputs of the block input muxes. Also shown are output muxes 66 and 68, which are used to produce the outputs for the system. Also shown is a multiplier unit 70 which can be used when the despreader/correlator units are not used. Thus, the despreader/correlator units and multiplier units share the adders input multiplexers and output multiplexers. Also shown in the despreader/correlator block 40 is the instruction which is provided to select the different multiplexers within the despreader/correlator block. In one embodiment, a decoder 72 is used to decode an instruction and produce the arrangements for the multiplexers within the system. For the system of FIG. 2, the different inputs using the input multiplexers can be provided to different elements such as the despreader/correlator trees, the multiplier units or the adder units. The outputs are connectable to a variety of different elements within the despreader/correlator block, including the multiplier units, the adders and the despreader/correlator trees. Also, as will be shown below, despreader/correlator tree units can be implemented in a number of different configurations controlled by the instruction.

FIG. 3 is a diagram that illustrates a number of different despreader/correlator trees that can be used with one embodiment of the present invention. The despreader/correlator trees include a number of complex multiplier units. Each tree uses a number of complex multiplier units, adder units and the tree of adder units. In the preferred embodiment, as will as described below, the complex multiplier unit multiplies two complex values. A 1-bit value, known as a code, and an 8-bit complex pair known as data. In one embodiment, all of the data goes through the adders before reaching the output multiplexer. Note that FIG. 3 does not illustrate the input buses.

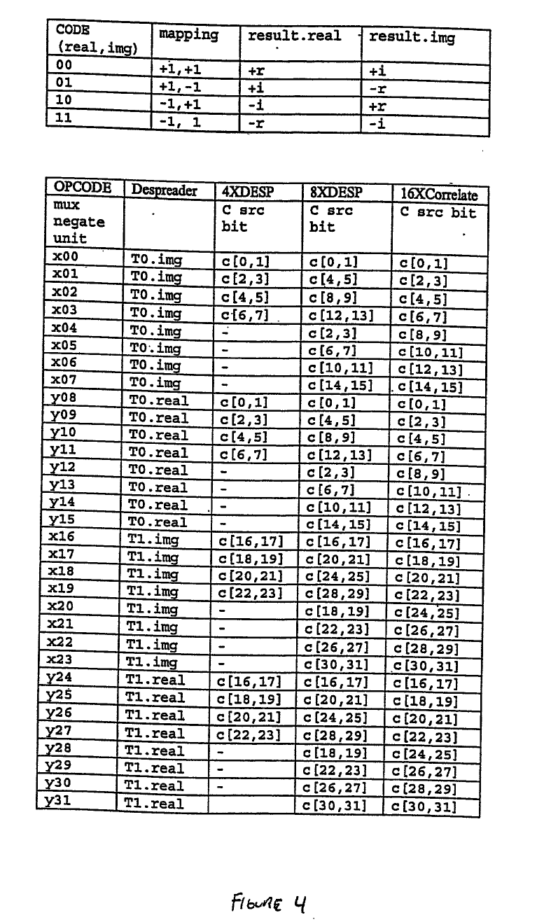

FIG. 4 includes the code bits which are used as the code portions of the complex multiplier in the despreador/correlator of FIG. 3.

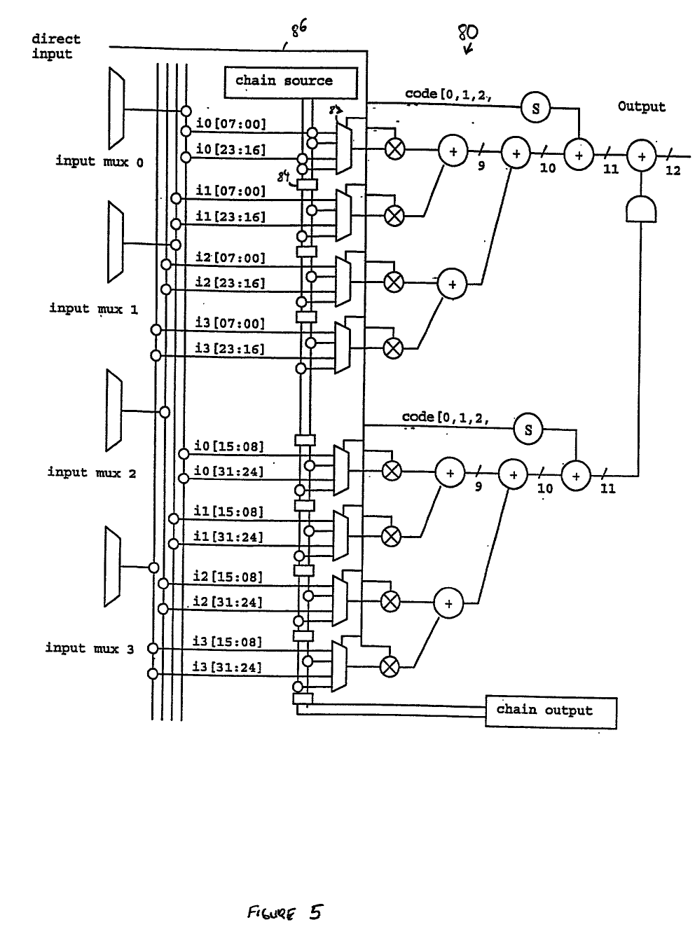

FIG. 5 is another diagram of one despreador/correlator. Note that the despreader/correlator tree 80 includes a number of complex multiplier units. The complex multiplier units including a multiplexer input 82, which can be used to select a number of different input values, either inputs directly from the input muxes or values which are sent through a chain source and associated registers 84. The inputs on the direct input line 86 preferably include the codes, or pseudo noise codes, used to arrange the despreader/correlator unit.

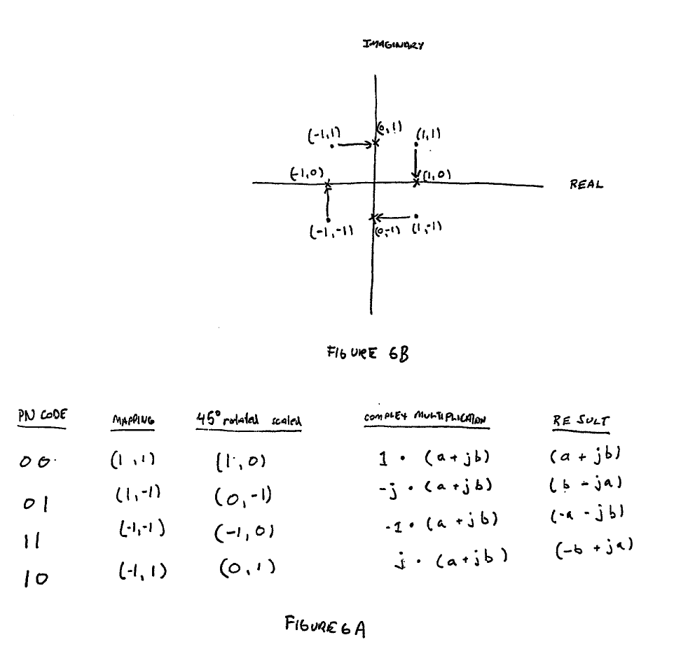

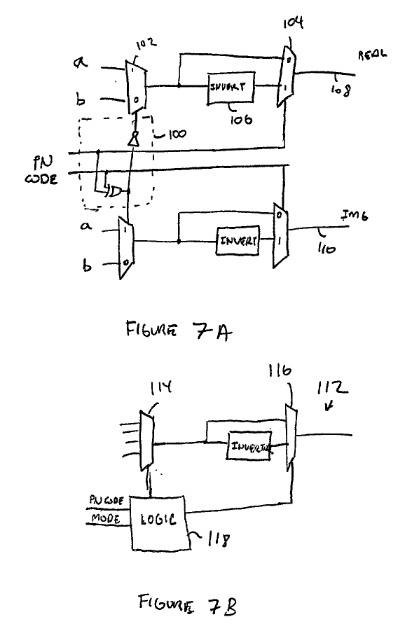

FIGS. 6A and 6B illustrate the operation of the complex multiplier in one embodiment of the present invention. The PN code inputs are mapped with zeros mapped to one, and ones mapped to negative one. This produces the corner values shown in FIG. 6B. It is desirable to instead have a 45° scaled rotation to use the values shown as crosses in FIG. 6B. Often this rotation is acceptable without later modification, when done consistently. Alternately, the complex values can be rotated back and re-scaled. The scaling factor has to do with the absolute values of the mapping shown in FIG. 6. FIG. 6A also shows an illustration of the multiplication of the rotated scaled values by data, which comprises of a real portion A, and an imaginary portion B.

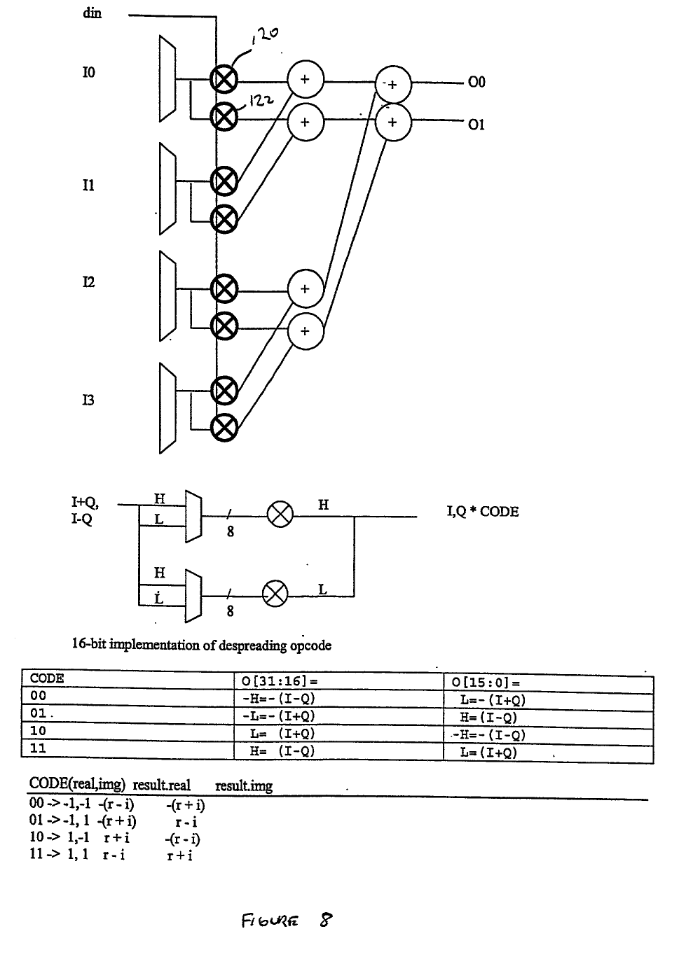

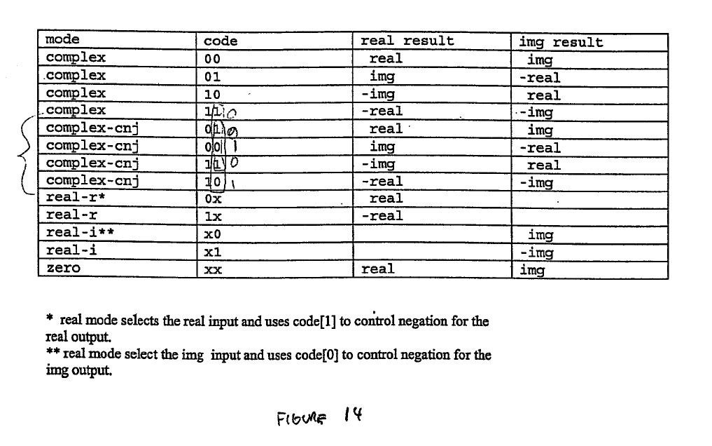

FIG. 7 is a diagram that illustrates the use of the PN codes and a multiplexer invertor unit to implement the complex multiplication of table 6A. Logic 100 is used to produce control signals for multiplexer units 102 and 104. Also used are an invertor unit 106. Thus, the real output on line 108 is either the positive or negative A or B as selected by the PN codes values sent to logic 100. Thus, for the system of FIG. 7A, where the PN code is 00, the output on the real line 108 is A, and the output on the imaginary line 110 is B. When the PN code is 01, output on line 108 is B, and the output on line 110 is negative A. When the PN code is 11, the output on line 108 is negative A, and the output on line 110 is negative B. When the PN code is 10, the output on line 108 is negative B, and the output on line 110 is A. Note that the system of FIG. 7A can be broken down into a half complex multiplier element. FIG. 7B, which is the base unit for use in the despreader/correlator trees. The half complex multiplier unit 112 includes two multiplexers 114 and 116. 114 selects the input, 116 selects between the inverted or regular value. The logic 118 receives the PN codes and any additional mode information. The modes are discussed with respect to FIG. 14 below. The logic 118 controls the multiplexers 114 and 116, and thus decides the output value of the half complex multiplier 112.

In one embodiment, the data can be pre-formatted with the real portion being A minus B and the data portion being A plus B. With this pre-formatting, the rotation discussed above need not be done.

FIG. 8 illustrates a 4-chip despreader, using two different codes. Shown in FIG. 8 are a number of 1-bit complex multiplier elements 120. In this example, 1-bit complex multiplier unit 120 is used along with a 1-bit complex multiplier unit 122 to provide a full complex multiplier.

In one embodiment, the despreader unit can despread 4 16-bit or 8 8-bit complex input samples, known as chips, to form two complex results corresponding to the pilot and data outputs of the despreader. Each input is stored as 8-bit complex data, and can be impact the 16-bit complex data.

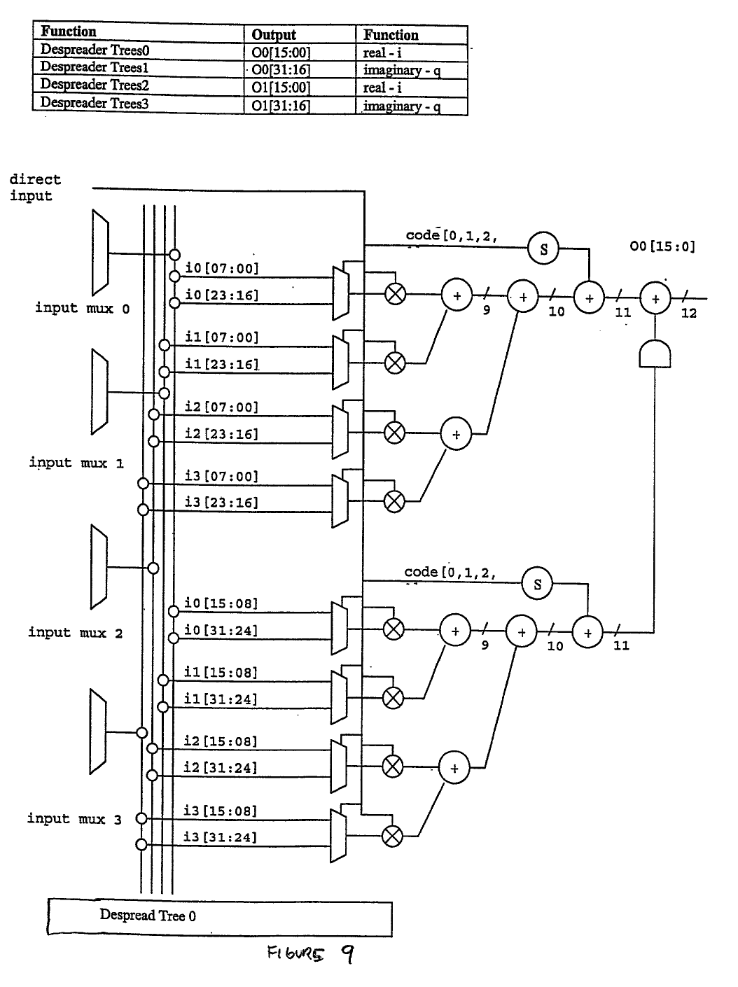

FIG. 9 illustrates a despreader tree. In this tree, four of the 16-bit or 8-bit complex samples are manipulated to provide an added real or imaginary portion. Thus, each of the 1-bit complex multiplier unit (half complex multiplier unit) can be used to select a real portion of a multiplied value. For the despreader tree of FIG. 9, 4 or 8, half multiplier output values are combined to provide the tree output value.

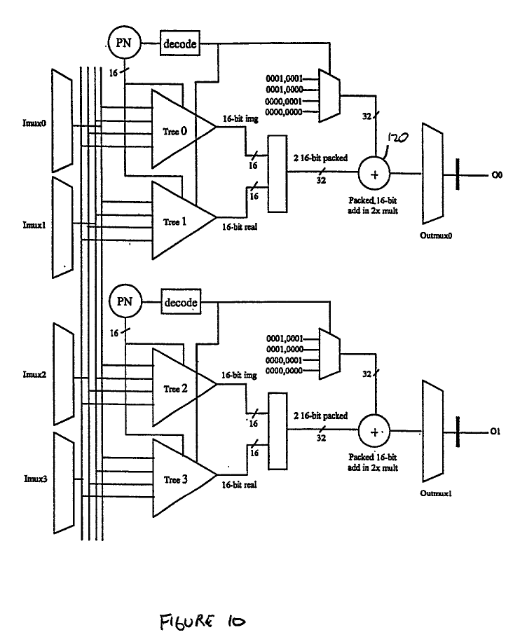

FIG. 10 illustrates a system of showing the despreader integration with the input and output muxes. Also shown is the use of the adder units, such as adder units 120, which can be implemented as an adder in the despreader/correlator block.

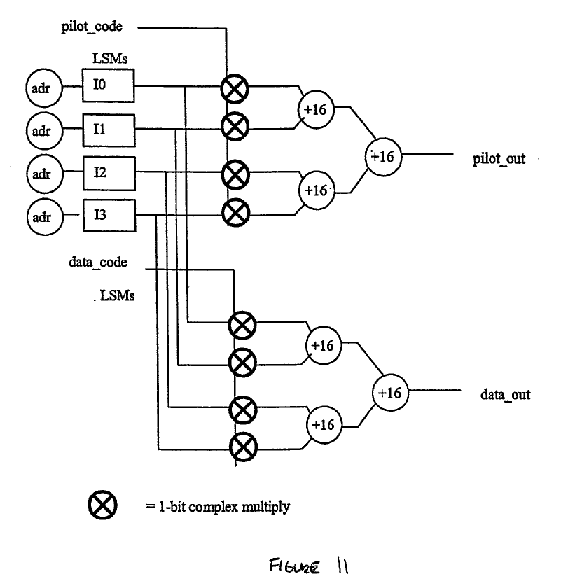

FIG. 11 illustrates another diagram of a despreader implementation.

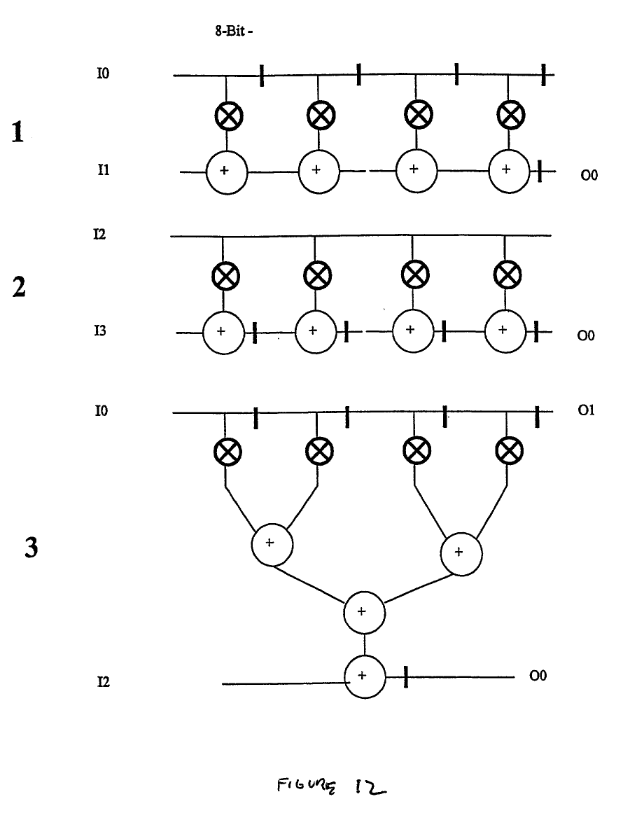

FIG. 12 shows how a chain correlation function can be implemented using the complex multiplier units and the delays. Looking at FIG. 5, as the chain source goes through the registers, it is delayed and then added together at the output, after all the complex multiplies.

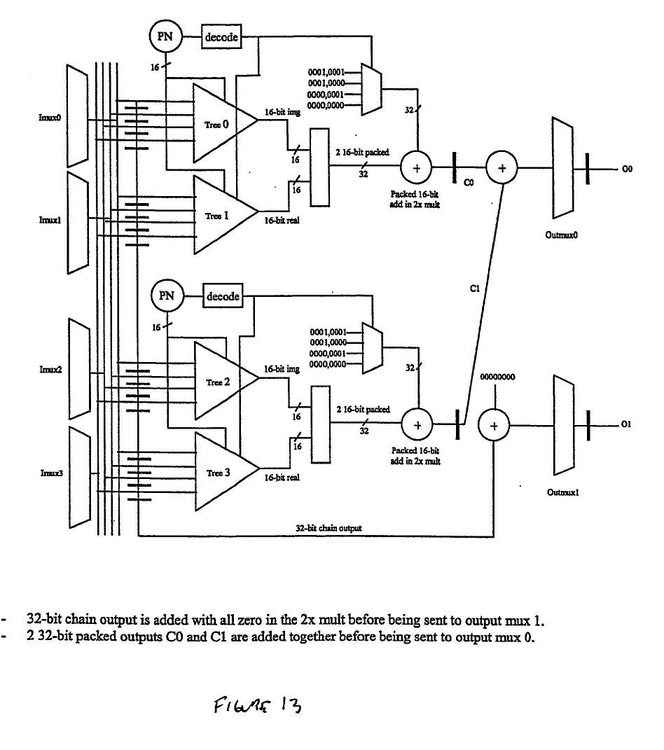

FIG. 13 illustrates an implementation of a correlator integrated with the input/output muxes, and the adder elements in the despreader/correlator block.

FIG. 14 illustrates a number of different modes that can be implemented, using the logic associated with the half complex multiplier unit 7B and different possible modes include the complex multiply, complex conjugate multiply, real value and zero value.

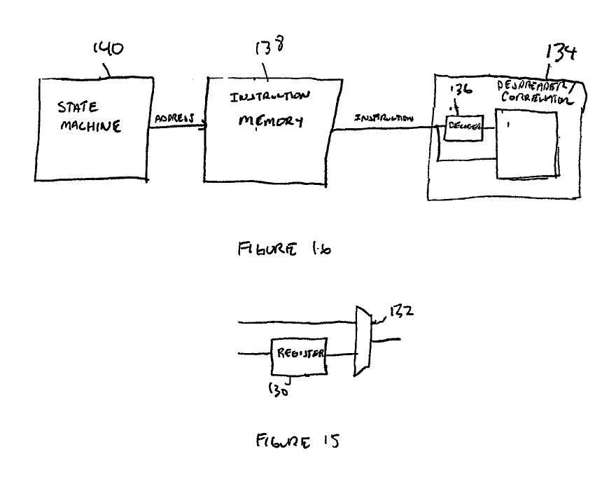

FIG. 15 illustrates a delay element which can be used in this present invention in which the register 130 can be selectively avoided by the multiplexer 132. Register 130 implements a delay.

FIG. 16 illustrates a system in which the despreader/correlator block 134 includes a decoder unit 136 which receives an instruction from an instruction memory 138. The instruction memory 138 can be addressed by state machine 140.

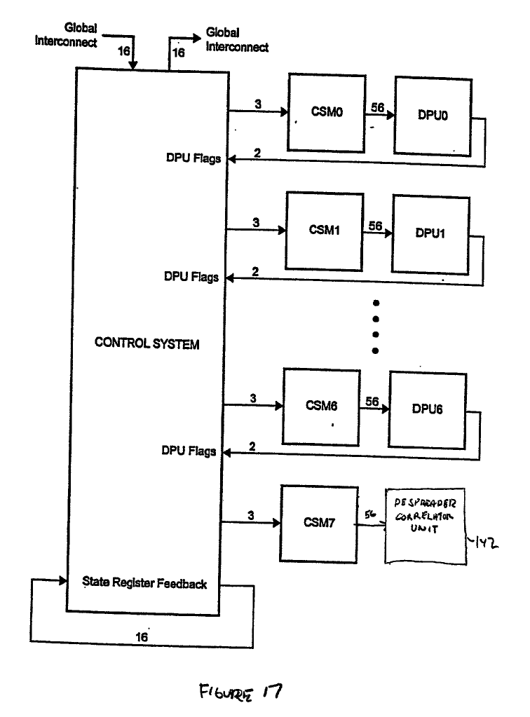

FIG. 17 illustrates a system in which a state machine controller unit addresses a number of different configuration state memories, including despreader/correlator unit 142.

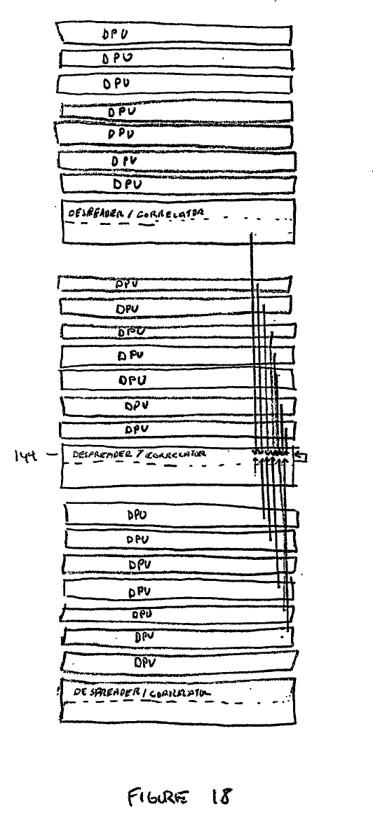

FIG. 18 illustrates the local connections for a despreader/correlator unit 144. In this embodiment, the despreader/correlator unit 144 is divided into two sections, each having two input multiplexers. Each of these two input blocks are connected to the eight elements above it and seven elements below it, along with a feedback of the output associated with that block. These local connections speed the operation of the system.

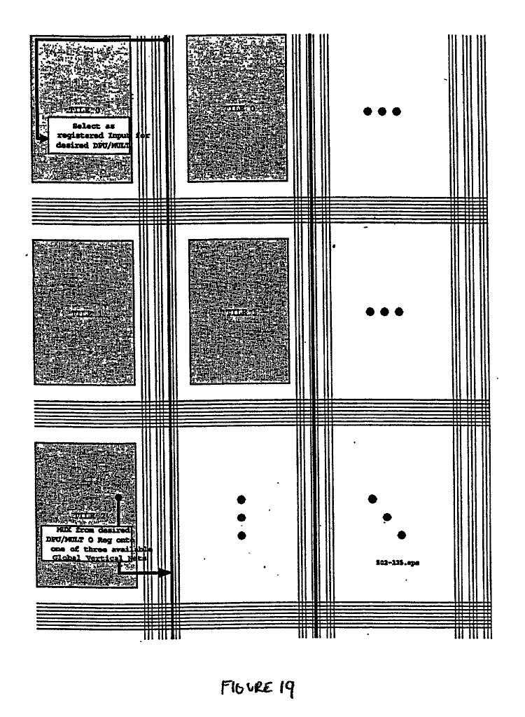

FIG. 19 illustrates a global connection wherein an element in the tile is connected to a global eluding system.

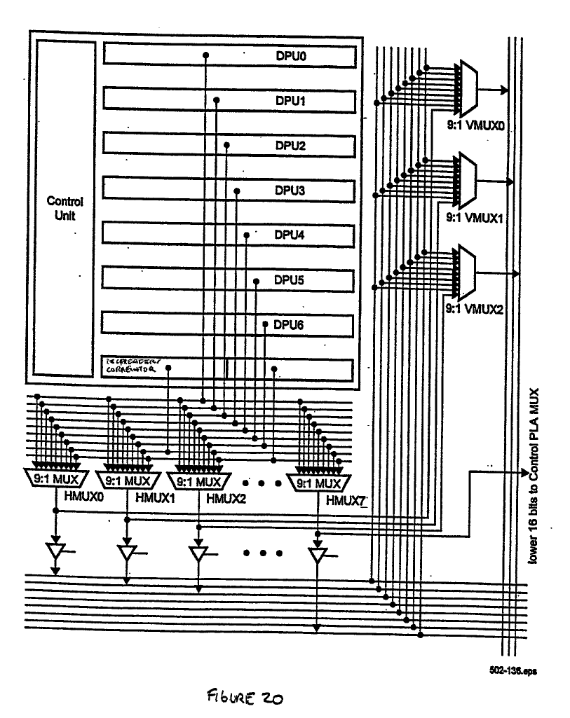

FIG. 20 how a despreader/correlator unit 20 can be connected to the variable connection buses. This allows for a global connection within the system.

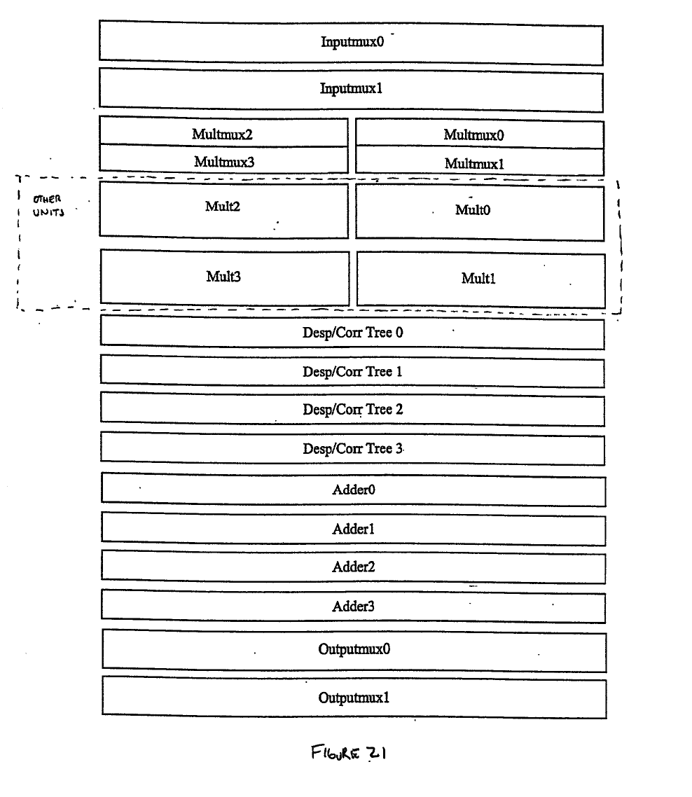

FIG. 21 shows a layout of the system of the present invention of the despreader/correlator unit of the present invention.

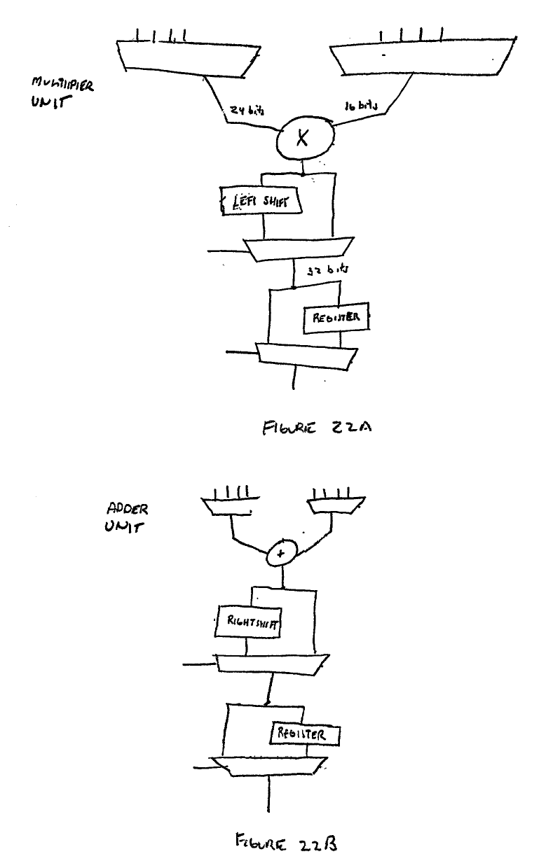

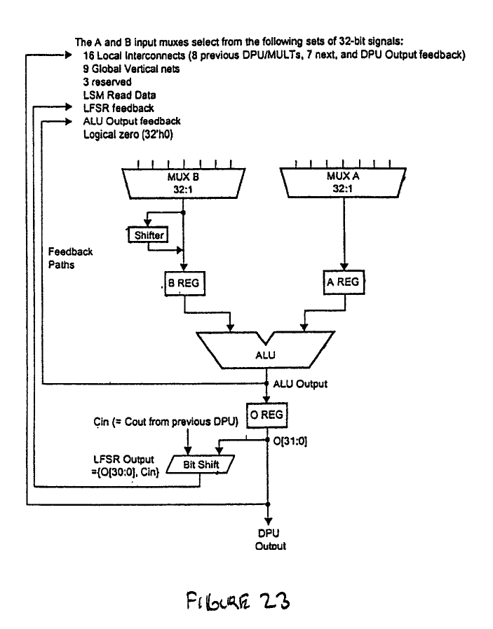

FIG. 22A illustrates a multiplier unit used in one embodiment of the present invention.

FIG. 22B illustrates an embodiment of the adder unit used in one embodiment of the present invention. An additional of the multiplier and adder units are given in the patent application entitled “Multiplier Unit in a Reconfigurable Chip” (BDSM No. 032001-078), incorporated herein by reference. An additional description of the despreader/correlators is given in Appendix 1. Description of the multiplier units is given in Appendix 2.

FIG. 23 illustrates a reconfigurable functional unit or data path unit, including an arithmetic logic unit, which can be used with the system of the present invention. Note that the arithmetic logic unit based system, by itself, cannot easily implement the despreader/correlator functions, so the use of the despreader/correlator units add to the effectiveness of the system of the present invention.

It will be appreciated by those of ordinary skill in the art that the invention can be implemented in other specific forms without departing from the spirit or character thereof. The presently disclosed embodiments are therefore considered in all respects to be illustrative and not restrictive. The scope of the invention is illustrated by the appended claims rather than the foregoing description, and all changes that come within the meaning and range of equivalents thereof are intended to be embraced herein.

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

[image]

What is claimed is:

1. A reconfigurable chip comprising:
a despreader function block including complex multiplier units, the despreader function block including multiplexers to allow the selection of different operation configurations for the despreader function block; and
interconnect elements operably connected to the despreader function block the interconnect elements adapted to selectively connect together the despreader function block with other reconfigurable units.

2. The reconfigurable chip of claim 1 wherein the complex multiplier unit comprises a complex half multiplier unit.

3. The reconfigurable chip of claim 1 wherein the complex half multiplier unit comprises a 1-bit complex half multiplier unit.

4. The reconfigurable chip of claim 3 wherein the 1-bit complex half multiplier is implemented using at least one multiplexer and an inverter.

5. The reconfigurable chip of claim 1 wherein the despreader function box can also implement a correlation function.

6. The reconfigurable chip of claim 1 wherein the despreader function block includes a number of despreader trees.

7. The reconfigurable chip of claim 1 wherein the despreader trees include a number of complex half multiplier units connected to adder units.

8. The reconfigurable chip of claim 1 wherein the despreader function block is controlled by an instruction stored in an associated instruction memory.

9. The reconfigurable chip of claim 1 wherein the despreader function block includes multiple block input multiplexers and at least one block output multiplexer.

10. A reconfigurable chip including:
a despreader function block including complex multiplier units, the despreader function block including multiplexers to allow the selection of different operation configurations for the despreader function block; and
an instruction memory storing multiple instructions for the despreader function block

11. The reconfigurable chip of claim 10 wherein the complex multiplier unit comprises a complex half multiplier unit.

12. The reconfigurable chip of claim 11 wherein the complex half multiplier units include at least one multiplexer and an inverter.

13. The reconfigurable chip of claim 10 wherein the despreader function block can also implement a correlator function.

14. The reconfigurable chip of claim 10 wherein the despreader function block can also implement a multiplication function.

15. The reconfigurable chip of claim 10 wherein the despreader function block includes despreader trees.

16. The reconfigurable chip of claim 15 wherein the despreader trees include complex half multiplier units and adders.

17. The reconfigurable chip of claim 10 wherein the despreader function block includes multiple block input multipliers and at least one block output multiplexer.

18. The reconfigurable chip of claim 10 further comprising interconnect elements operably connected to the despreader function block, the interconnect elements adapted to selectively connect the other despreader function block with other reconfigurable units.

19. A despreader function block on a reconfigurable chip, the despreader function block including:
multiple block input multiplexers;
despreader tree units including complex multiplier units, the despreader tree units operably connected to the multiple block input multiplexers; and
at least one block output multiplexer operably connected to the selectable despreader tree units.

20. The despreader function block of claim 19 wherein the complex multiplier units comprise complex half multiplier units.

21. The despreader function block of claim 19 wherein the complex half multiplier units comprise a multiplexer and an inverter.

22. The despreader function block of claim 19 wherein the despreader tree units further include adder elements.

23. A reconfigurable chip including the despreader function block of claim 19.

24. The reconfigurable chip of claim 23 further comprising an interconnect element operably connected to the despreader function block to operably connect together the despreader function block with other reconfigurable units.

25. The reconfigurable chip of claim 23 further comprising an instruction memory showing multiple instructions for the despreader function block.

26. The despreader function block of claim 19 wherein the despreader tree units can also implement correlation functions.

27. The despreader function block of claim 19 wherein the despreader function block can also implement a multiplication function.

28. A reconfigurable chip comprising:
multiple despreader blocks, the despreader blocks adapted to despread input signals using an PN sequence, the selectable blocks also being selectable to a non-despreader function; and
reconfigurable functional units operably connectable to the despreader blocks, the reconfigurable functional units including an arithmetic logic unit.

29. The reconfigurable chip of claim 28 wherein the despreader function block include complex half multiplier units.

30. The reconfigurable chip of claim 28 wherein the complex half multiplier units are implemented using multiplexers and an inverter.

31. The reconfigurable chip of claim 28 wherein the despreader function blocks are implemented using a despreader tree.

32. The reconfigurable chip of claim 31 wherein the despreader tree is implemented using a number of complex half multiplier units and adders.

33. The reconfigurable chip of claim 28 wherein the despreader blocks can also implement a correlator function.

34. The reconfigurable chip of claim 28 wherein the despreader blocks can also implement a multiplication function.

35. The reconfigurable chip of claim 28 further comprising interconnect elements operably connected to the despreader function block to interconnect between the reconfigurable functional units and the despreader blocks.

36. The reconfigurable chip of claim 28 wherein input multiplexers for the despreader blocks can be selected to connect to operative nearby reconfigurable functional units.

37. The reconfigurable chip of claim 28 wherein the despreader function block includes multiplexers and at least one block output multiplexer.

38. The reconfigurable chip of claim 28 further comprising an instruction memory storing multiple instructions for the despreader function block.
